(19) United States
(12) Patent Application Publication
(10) Pub. No.: US 2025/0070015 A1
(43) Pub. Date: Feb. 27, 2025

(54) SEMICONDUCTOR DIE STUCTURE WITH AIR GAPS AND METHOD FOR PREPARING THE SAME

(71) Applicant: NANYA TECHNOLOGY CORPORATION, NEW TAIPEI CITY (TW)

(72) Inventor: CHIN-LING HUANG, TAOYUAN CITY (TW)

(21) Appl. No.: 18/509,629

(22) Filed: Nov. 15, 2023

Related U.S. Application Data
(62) Division of application No. 18/237,015, filed on Aug. 23, 2023.

(51) Int. Cl. H01L 23/522; H01L 23/528; H01L 23/532

(52) U.S. Cl. CPC H01L 23/5222; H01L 23/5283; H01L 23/53238; H01L 23/53252; H01L 23/5329

(57) ABSTRACT

The present disclosure provides a semiconductor die structure including a substrate, a first supporting backbone, a first conductor block, and an air gap structure. The first supporting backbone is disposed on the substrate. The first conductor block is disposed on the first supporting backbone, and includes a first barrier layer and a first conductive layer disposed in the first barrier layer. The air gap structure is disposed on the substrate and in contact with the first supporting backbone and the first conductor block.

### CROSS-REFERENCE TO RELATED APPLICATION

This application is a divisional application of U.S. Non-Provisional application Ser. No. 18/237,015 filed Aug. 23, 2023, which is incorporated herein by reference in its entirety.

### TECHNICAL FIELD

The present disclosure relates to a semiconductor die structure and a method for preparing the semiconductor die structure, and more particularly, to a semiconductor die structure with air gaps for reducing capacitive coupling between conductive features and a method for preparing the same.

### DISCUSSION OF THE BACKGROUND

Semiconductor dies are widely used in electronics industries. Semiconductor dies may have relatively small sizes, multi-functional characteristics, and/or relatively low manufacture costs. Semiconductor dies may be categorized as any one of semiconductor memory dies storing logical data, semiconductor logic dies processing logical data, and hybrid semiconductor dies having both the function of the semiconductor memory dies and the function of the semiconductor logic dies.

Relatively high-speed and relatively low-voltage semiconductor dies may satisfy desired characteristics (e.g., high speed and/or low power consumption) of electronic dies including semiconductor dies. Semiconductor dies may be relatively highly integrated. Reliability of semiconductor dies may be reduced by relatively high integration density of the semiconductor dies.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor die structure including a substrate, a first supporting backbone, a first conductor block, and an air gap structure. The first supporting backbone is disposed on the substrate. The first conductor block is disposed on the first supporting backbone, and includes a first barrier layer and a first conductive layer disposed in the first barrier layer. The air gap structure is disposed on the substrate and in contact with the first supporting backbone and the first conductor block.

Another aspect of the present disclosure provides a semiconductor die structure including a substrate, a first supporting backbone, a second supporting backbone, a first conductor block, a second conductor block, and third conductor blocks. The first supporting backbone and the second supporting backbone are disposed on the substrate. The first conductor block is disposed on the first supporting backbone, and the second conductor block is disposed on the second supporting backbone. The third conductor blocks are disposed between the first conductor block and the second conductor block. The third conductor blocks are suspended on the substrate.

Yet another aspect of the present disclosure provides a method for preparing a semiconductor die structure, including: forming a first supporting backbone on the substrate; forming a first conductor block on the first supporting backbone; after forming the first conductor block, forming a second supporting backbone on the substrate; forming a second conductor block on the second supporting backbone; forming third conductor blocks suspended above the substrate; sequentially forming an energy removable layer and a capping dielectric layer over the substrate, wherein the first conductor block, the second conductor block and the third conductor blocks are spaced apart to each other by the energy removable layer; and performing a heat treatment process to transform the energy removable layer into an air gap structure including an air gap and a liner layer enclosing the air gap.

Embodiments of the semiconductor die structure are provided in the disclosure. The semiconductor die structure includes a plurality of air gaps, and the conductor blocks are separated from the each other by the air gaps. Therefore, the parasitic capacitance between the conductive contacts may be reduced. As a result, the overall device performance may be improved (i.e., the decreased power consumption and resistive-capacitive (RC) delay), and the yield rate of the semiconductor device may be increased.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a method for fabricating a semiconductor structure with air gaps for reducing capacitive coupling between conductive features such as lines and wires according to some embodiments of the present disclosure.

FIG. 2 is a cross-sectional view illustrating an intermediate stage in the formation of the semiconductor die structure, in accordance with some embodiments of the present disclosure.

FIG. 3 is a cross-sectional view illustrating an intermediate stage of forming a carbon hard mask in the formation of the semiconductor die structure, in accordance with some embodiments of the present disclosure.

FIG. 4 is a cross-sectional view illustrating an intermediate stage of forming a spacer opening in the formation of the semiconductor die structure, in accordance with some embodiments.

FIG. 5 is a cross-sectional view illustrating an intermediate stage of forming the supporting backbone in the formation of the semiconductor die structure, in accordance with some embodiments of the present disclosure.

FIG. 6 is a cross-sectional view illustrating an intermediate stage of forming a conductor block in the formation of the semiconductor die structure, in accordance with some embodiments of the present disclosure.

FIG. 7 is a cross-sectional view illustrating an intermediate stage of performing a planarization process in the formation of the semiconductor die structure, in accordance with some embodiments of the present disclosure.

FIG. 8 is a cross-sectional view illustrating an intermediate stage of performing a recessing process in the formation of the semiconductor die structure, in accordance with some embodiments of the present disclosure.

FIG. 9 is a cross-sectional view illustrating an intermediate stage of forming a metal silicide layer in the formation of the semiconductor die structure, in accordance with some embodiments of the present disclosure.

FIG. 10 is a cross-sectional view illustrating an intermediate stage of forming a first hard mask in the formation of the semiconductor die structure, in accordance with some embodiments of the present disclosure.

FIG. 11 is a cross-sectional view illustrating an intermediate stage of performing an etching process in the formation of the semiconductor die structure, in accordance with some embodiments of the present disclosure.

FIG. 12 is a cross-sectional view illustrating an intermediate stage of performing an etching process in the formation of the semiconductor die structure, in accordance with some embodiments of the present disclosure.

FIG. 13 is a cross-sectional view illustrating an intermediate stage of performing a deposition process in the formation of the semiconductor die structure, in accordance with some embodiments of the present disclosure.

FIG. 14 is a cross-sectional view illustrating an intermediate stage of forming a second supporting backbone in the formation of the semiconductor die structure, in accordance with some embodiments of the present disclosure.

FIG. 15 is a cross-sectional view illustrating an intermediate stage of forming a conductor block in the formation of the semiconductor die structure, in accordance with some embodiments of the present disclosure.

FIG. 16 is a cross-sectional view illustrating an intermediate stage of forming a second hard mask in the formation of the semiconductor die structure, in accordance with some embodiments of the present disclosure.

FIG. 17 is a cross-sectional view illustrating an intermediate stage of removing the spacer layer in the formation of the semiconductor die structure, in accordance with some embodiments of the present disclosure.

FIG. 18 is a cross-sectional view illustrating an intermediate stage of forming an energy removable layer and a capping dielectric layer in the formation of the semiconductor die structure, in accordance with some embodiments of the present disclosure.

FIG. 19 is a cross-sectional view illustrating an intermediate stage of forming air gaps and liner layers in the formation of the semiconductor die structure, in accordance with some embodiments of the present disclosure.

FIG. 20 is a schematic illustration of an exemplary integrated circuit, such as a memory device, including an array of memory cells in accordance with some embodiments.

FIG. 21 is a cross-sectional view illustrating a semiconductor die structure, in accordance with other embodiments of the present disclosure.

FIG. 22 is a cross-sectional view illustrating a semiconductor die structure, in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the die in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor die generally means a die which can function by utilizing semiconductor characteristics, and an electro-optic die, a light-emitting display die, a semiconductor circuit, and an electronic die are all included in the category of the semiconductor die.

It should be noted that, in the description of the present disclosure, above (or up) corresponds to the direction of the arrow of the direction Z, and below (or down) corresponds to the opposite direction of the arrow of the direction Z.

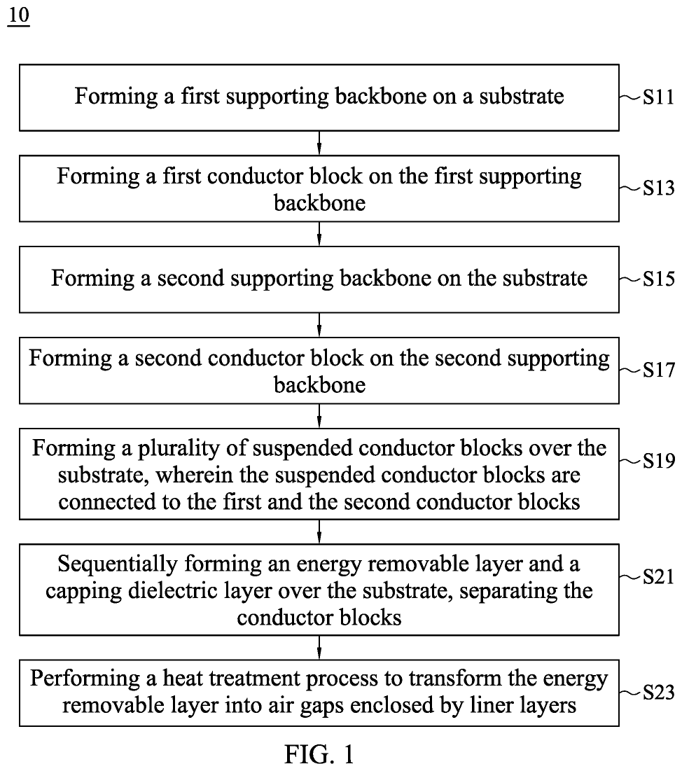

FIG. 1 illustrates a method 10 for fabricating a semiconductor structure with air gaps for reducing capacitive coupling between conductive features such as lines and wires according to some embodiments of the present disclosure. The method 10 may be performed as operations. It may be noted that the method 10 may be performed in any order and may include the same, more, or fewer operations. It may be noted that the method 10 may be performed by one or more pieces of semiconductor fabrication equipment or fabrication tools. In some embodiments, the method 10 includes steps S11, S13, S15, S17, S19, S21 and S23. The steps S11 to S23 of FIG. 1 are elaborated in connection with following figures.

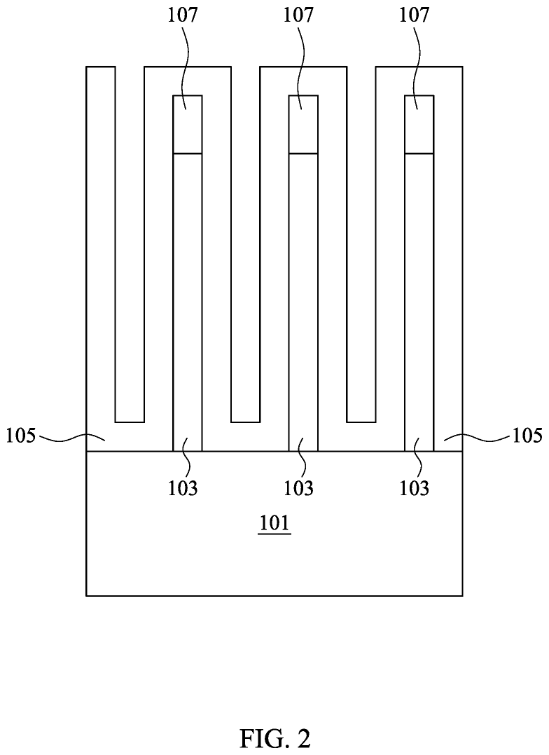

In some embodiments, referring to FIGS. 2-5, at the step S11 in the method 10 shown in FIG. 1, fabrication processes are performed to form a first supporting backbone 111 on a substrate 101.

In some embodiments, the substrate 101 may be a semiconductor wafer such as a silicon wafer. Alternatively or additionally, the substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

In some embodiments, the substrate 101 includes an epitaxial layer. For example, the substrate 101 has an epitaxial layer overlying a bulk semiconductor. In some embodiments, the substrate 101 is a semiconductor-on-insulator substrate which may include a substrate, a buried oxide layer over the substrate, and a semiconductor layer over the buried oxide layer, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other applicable methods.

In some embodiments, the substrate 101 may be a variety of materials, including, but not limited to, sapphire, silicon, gallium is nitride (GaN), germanium, or silicon carbide. The substrate 101 may be silicon on insulator (SOI). In some embodiments of the present disclosure, the substrate 101 is silicon. crystallographic orientation of a substantially monocrystalline substrate 101 may be any of (100), (111), or (110) on the Miller Indices. Other crystallographic orientations are also possible. The crystallographic orientations of substrate 101 may be offcut. In some embodiments of the present disclosure, the substrate 101 is (100) silicon with crystalline substrate surface region having cubic crystallinity. In another embodiment, for a (100) silicon substrate 101, the semiconductor surface may be miscut, or offcut, for example 2-10 degree toward (110). In another embodiment, substrate 101 is (111) silicon with crystalline substrate surface region having hexagonal crystallinity.

FIG. 2 is cross-sectional views illustrating an intermediate stage in the formation of the semiconductor die structure 100, in accordance with some embodiments of the present disclosure. In some embodiments, a plurality of silicon-containing lines 103 such as polysilicon lines may be disposed or grown over the substrate 101. The silicon-containing lines 103 may include a pattern at twice the final pitch (e.g., pitch is the width of a metal line plus the spacing between two metal lines) and capped with a hard mask 107. The hard mask 107 may include SiN. The silicon-containing lines 103 may be patterned on SiN, SiC, or alumina. A spacer layer 105 (e.g., silicon oxide) may be fabricated on the silicon-containing lines 103. It may be noted that a buffer layer (not shown) may be disposed between the silicon-containing lines 103 and substrate 101. An appropriate buffer layer may be disposed corresponding to the material type of substrate 101.

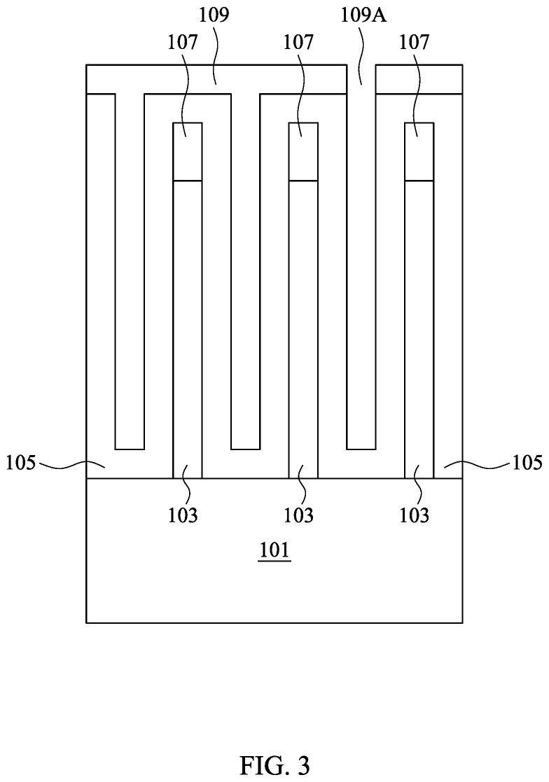

FIG. 3 is a cross-sectional view illustrating an intermediate stage of forming a carbon hard mask 109 in the formation of the semiconductor die structure 100, in accordance with some embodiments of the present disclosure. In some embodiments, the carbon hard mask 109 is formed on the spacer layer 105 by the deposition process, and a mask opening 109A is then formed in the carbon hard mask 109 by lithographically patterning.

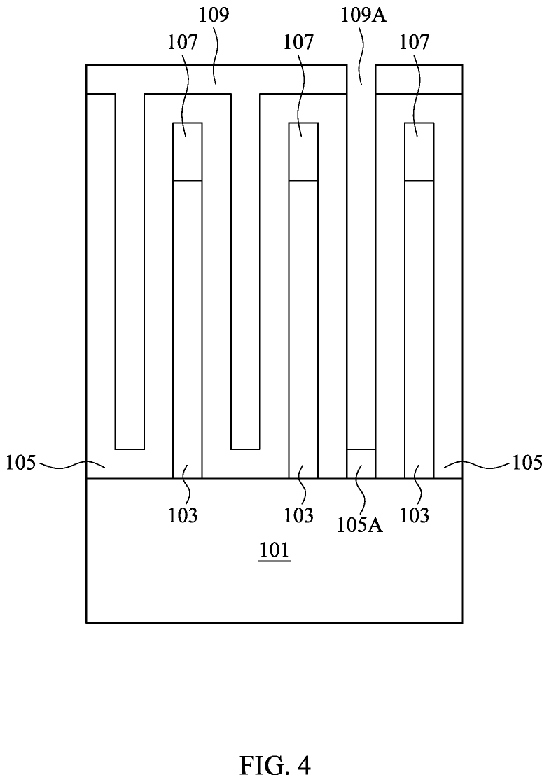

FIG. 4 is a cross-sectional view illustrating an intermediate stage of forming a spacer opening 105A in the formation of the semiconductor die structure 100, in accordance with some embodiments. In some embodiments, an etching process is performed to transfer the mask opening 109A into the spacer opening 105A of the spacer layer 105.

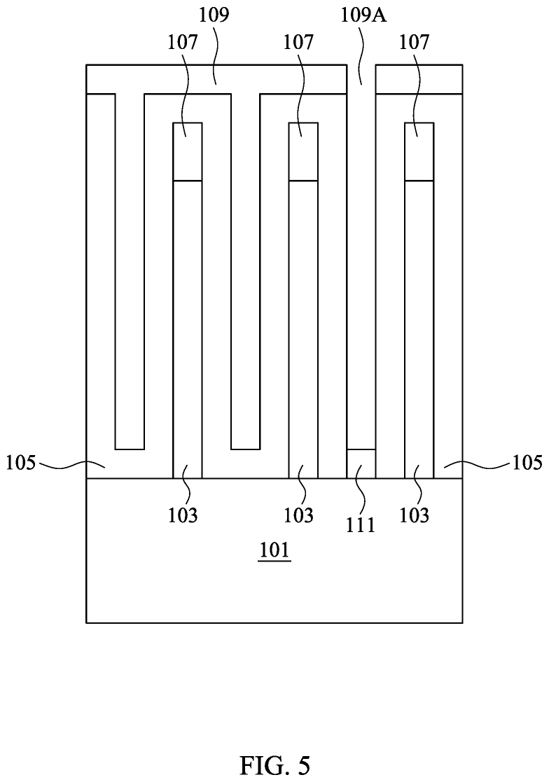

FIG. 5 is a cross-sectional view illustrating an intermediate stage of forming the supporting backbone 111 in the formation of the semiconductor die structure 100, in accordance with some embodiments of the present disclosure. In some embodiments, the supporting backbone 111 may be fabricated by using a spin-on technique. The material of the supporting backbone 111 can be a spin-on metallic oxide (tungsten oxide, hafnium oxide, or zirconium oxide) that is deposited only up to a threshold height. The supporting backbone 111 may be a spin-on dielectric that has Si—C—Si (e.g., not Si—O—Si) in the backbone and that is properly cured to withstand hydrofluoric (HF) acid. In another embodiment, a non-conformal SiN, SiC, or SiCN may be used (e.g., instead of a spin-on) which may leave a thin etch stop layer on the oxide spacer and may help protect the metal barrier from the HF strip during the subsequent air gap formation.

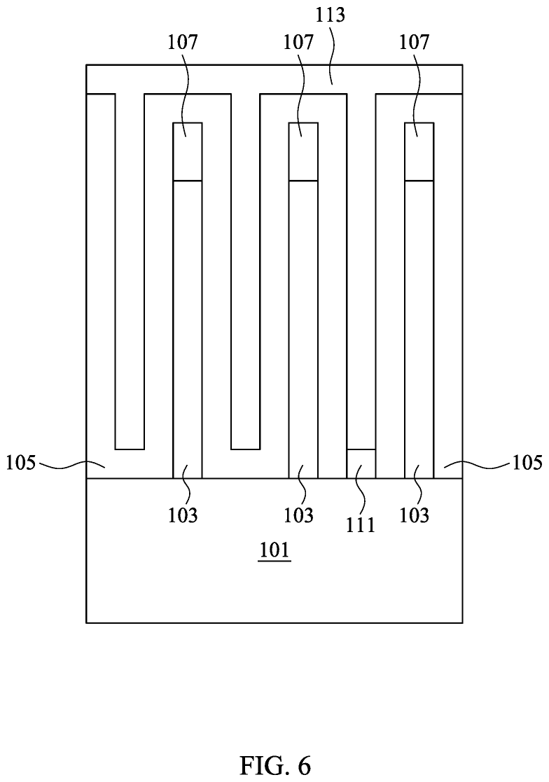

FIG. 6 is a cross-sectional view illustrating an intermediate stage of forming a conductor block 113 in the formation of the semiconductor die structure 100, in accordance with some embodiments of the present disclosure. In some embodiments, the carbon hard mask 109 is removed (e.g., the carbon hard mask 109 is ashed away) and the conductor block 113 fills the regions between the spacer layer 105. The conductor block 113 may be a recessable material such as cobalt (Co), copper (Cu), ruthenium (Ru), or amorphous silicon (a-Si) (e.g., a-Si which is silicided later to form CoSi or NiSi).

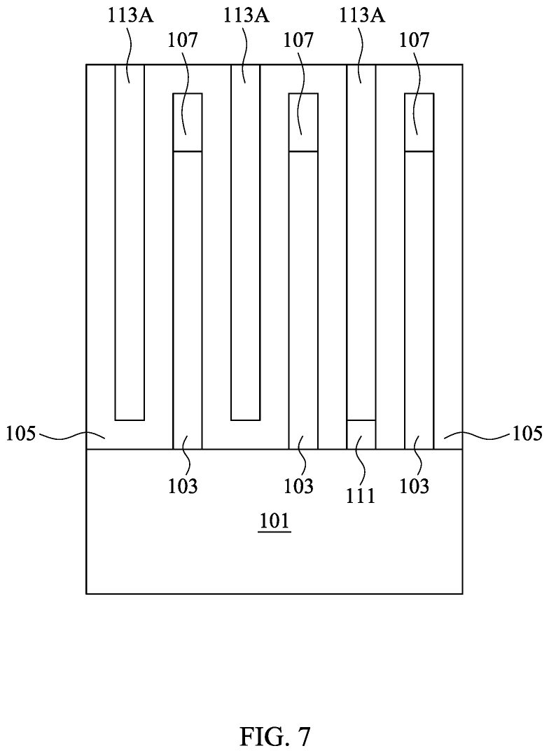

FIG. 7 is a cross-sectional view illustrating an intermediate stage of performing a planarization process in the formation of the semiconductor die structure 100, in accordance with some embodiments of the present disclosure. At the step S13 in the method 10 shown in FIG. 1, a first conductor block is formed on the first supporting backbone. In some embodiments, a planarization process such as a chemical mechanical polishing (CMP) process is performed to remove a portion of the metal layer 113, such that the spacer layer 105 is exposed. In some embodiments, after the planarization process, a plurality of conductor blocks 113A are embedded in the spacer layer 105, wherein the top ends of the conductor blocks 113A are substantially the same as that of the spacer layer 105. In other words, the top ends of the conductor blocks 113A are coplanar with top ends of the spacer layer 105.

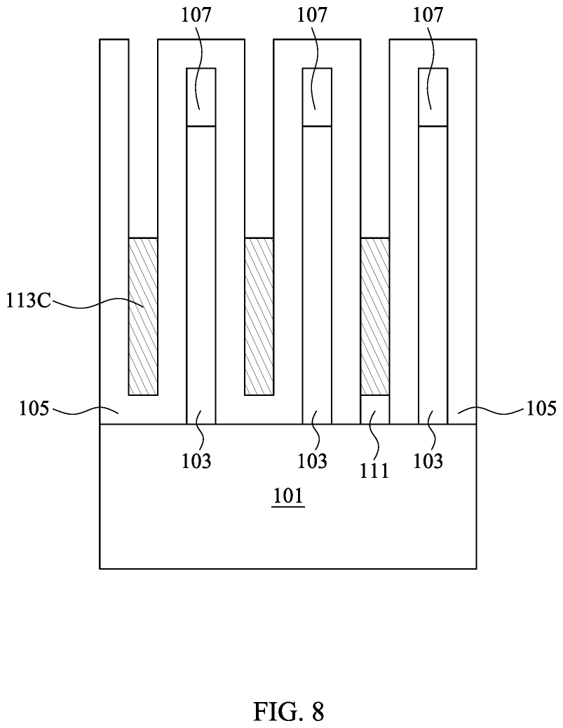

FIG. 8 is a cross-sectional view illustrating an intermediate stage of performing a recessing process in the formation of the semiconductor die structure 100, in accordance with some embodiments of the present disclosure. In some embodiments, a portion of the conductor blocks 113A is removed by a recessing process such as an etching back process to form a plurality of conductor blocks 113B embedded in the spacer layer 105, wherein the top ends of the conductor blocks 113B are lower than that of the spacer layer 105.

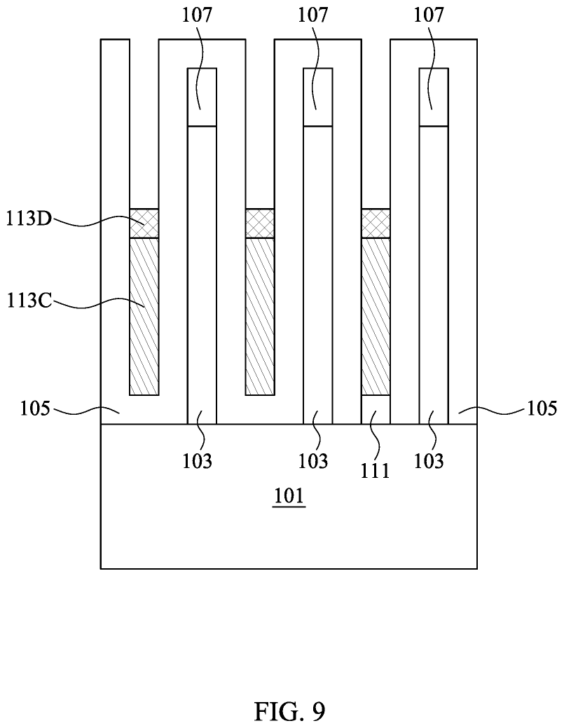

FIG. 9 is a cross-sectional view illustrating an intermediate stage of forming a metal silicide layer 113D in the formation of the semiconductor die structure 100, in accordance with some embodiments of the present disclosure. In some embodiments, when the conductor block 113C is a-Si, metal may be deposited on the conductor block 113C and annealed to form the metal silicide layer 113D over the conductor block 113C. In some embodiments, metal nickel (Ni) may be deposited and annealed to form nickel silicide (NiSi) or metal cobalt (Co) may be deposited and annealed to form cobalt silicide (CoSi).

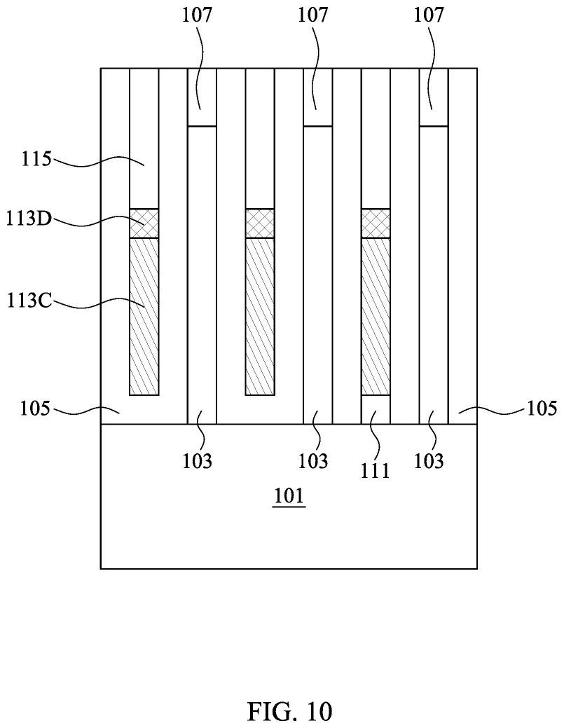

FIG. 10 is a cross-sectional view illustrating an intermediate stage of forming a first hard mask 115 in the formation of the semiconductor die structure 100, in accordance with some embodiments of the present disclosure. In some embodiments, a deposition process is performed to form the first hard mask 115 over the metal silicide layer 113D and a planarization process is then performed on the first hard mask 115. In some embodiments, the first hard mask 115 may include SiC, SiOC, ZrO2, HfO2, or W oxide. In some embodiments, the first hard mask 115 may be one or more of a dielectric, a carbide, or a metallic carbide. After forming the first hard mask layer 115, the conductor block 113C and the metal silicide layer 113D capped with the first hard mask 115 may be referred to as a metal line or a wire.

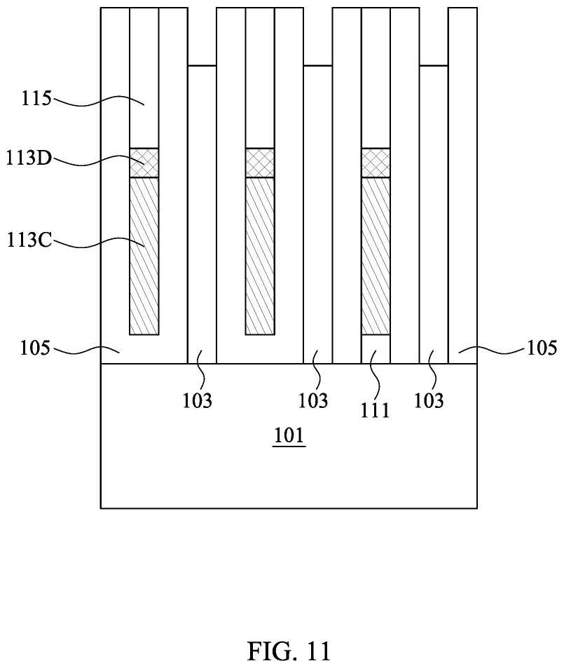

FIG. 11 is a cross-sectional view illustrating an intermediate stage of performing an etching process in the formation of the semiconductor die structure 100, in accordance with some embodiments of the present disclosure. In some embodiments, the hard mask 107 is removed to expose the silicon-containing lines 103 by an etching process such as a dry etching process to selectively remove the hard mask 107, while remaining the silicon-containing lines 103 on the substrate 101.

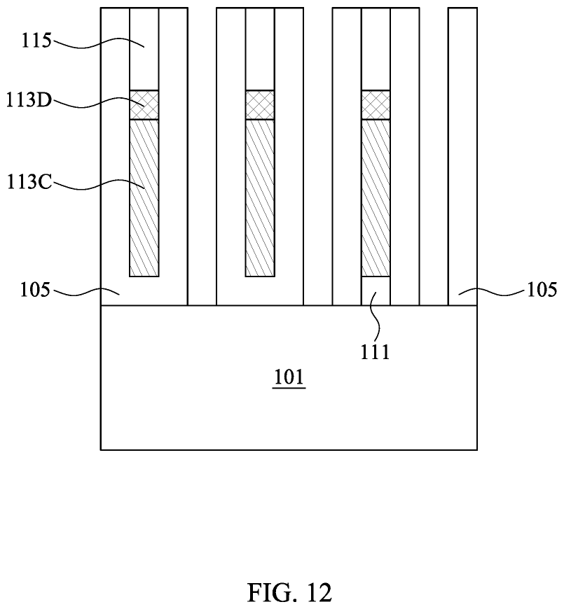

FIG. 12 is a cross-sectional view illustrating an intermediate stage of performing an etching process in the formation of the semiconductor die structure 100, in accordance with some embodiments of the present disclosure. In some embodiments, the silicon-containing lines 103 are etching out to expose portions of the substrate 101, while remaining the spacer layer 105 on the substrate 101.

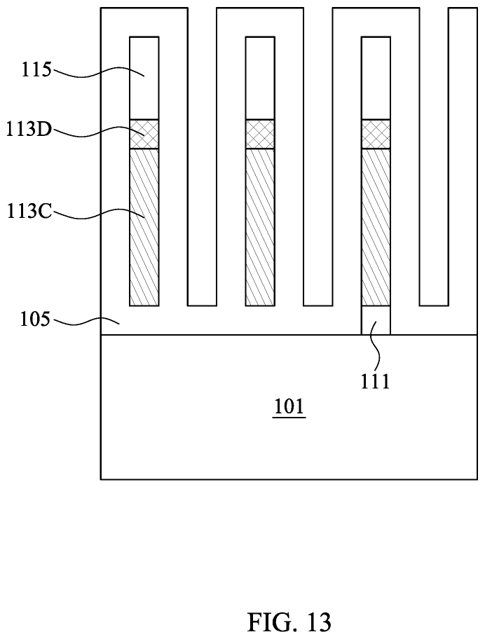

FIG. 13 is a cross-sectional view illustrating an intermediate stage of performing a deposition process in the formation of the semiconductor die structure 100, in accordance with some embodiments of the present disclosure. In some embodiments, the deposition process is performed to deposit material of the spacer layer 105 on at least the exposed portions of the substrate 101 and the first hard mask 115.

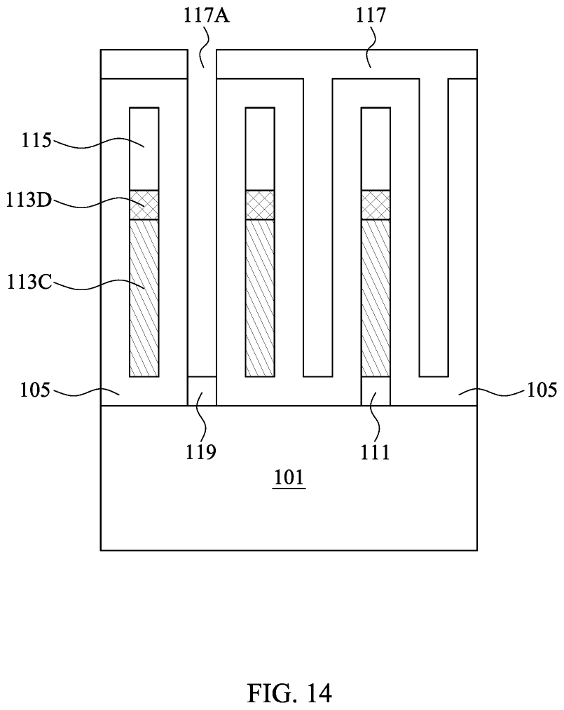

FIG. 14 is a cross-sectional view illustrating an intermediate stage of forming a second supporting backbone in the formation of the semiconductor die structure 100, in accordance with some embodiments of the present disclosure. At the step S15 in the method 10 shown in FIG. 1, a second supporting backbone 119 is formed on the substrate 101. In some embodiments, similar to the fabrication processes described in FIGS. 3-5, a carbon hard mask 117 is formed on the spacer layer 105 by the deposition process, and a mask opening 117A is then formed in the carbon hard mask 117 by lithographically patterning. In some embodiments, an etching process is performed to transfer the mask opening 117A into a spacer opening of the spacer layer 105 to expose a portion of the substrate 101. Subsequently, the supporting backbone 119 is then formed on the exposed portion of the substrate 101.

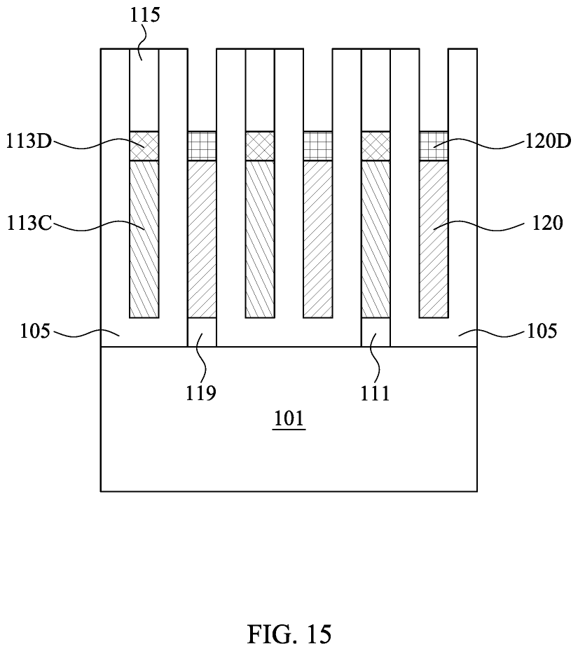

FIG. 15 is a cross-sectional view illustrating an intermediate stage of forming a conductor block 120 in the formation of the semiconductor die structure 100, in accordance with some embodiments of the present disclosure. At the step S17 in the method 10 shown in FIG. 1, a second conductor block 120 is formed on the second supporting backbone 119. In some embodiments, similar to the fabrication processes described in FIGS. 6-9, the carbon hard mask 117 is removed (e.g., the carbon hard mask 117 is ashed away) and the conductor block 120 fills the regions between the spacer layer 105. The conductor block 120 may be a recessable material such as cobalt (Co), copper (Cu), ruthenium (Ru), or amorphous silicon (a-Si) (e.g., a-Si which is silicided later to form CoSi or NiSi).

In some embodiments, a planarization process such as a chemical mechanical polishing (CMP) process is performed to remove a portion of the conductor block 120, such that the spacer layer 105 is exposed. In some embodiments, after the planarization process, the conductor block 119 is embedded in the spacer layer 105, wherein the top end of the conductor block 120 is substantially the same as that of the spacer layer 105. In some embodiments, a recessing process such as an etching back process is then performed to remove a portion of the conductor block 120, wherein the top end of the conductor block 120 is substantially the same as that of the spacer layer 105.

In some embodiments, when the conductor block 120 is a-Si, metal may be deposited and annealed to form a metal silicide layer 120D over the conductor block 120. In some embodiments, metal nickel (Ni) may be deposited and annealed to form nickel silicide (NiSi) or metal cobalt (Co) may be deposited and annealed to form cobalt silicide (CoSi).

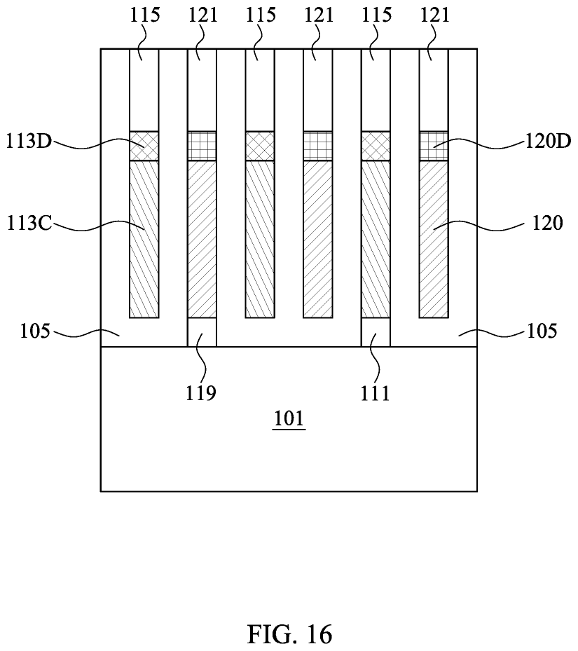

FIG. 16 is a cross-sectional view illustrating an intermediate stage of forming a second hard mask 121 in the formation of the semiconductor die structure 100, in accordance with some embodiments of the present disclosure. In some embodiments, a deposition process is performed to form the second hard mask 121 over the metal silicide layer 120D and a planarization process is then performed on the second hard mask 121. In some embodiments, the second hard mask 121 may include SiC, SiOC, ZrO2, HfO2, or W oxide. In some embodiments, the second hard mask 121 may be one or more of a dielectric, a carbide, or a metallic carbide. After forming the second hard mask 121, the conductor block 120 and the metal silicide layer 120 capped with the second hard mask 121 may be referred to as a metal line or a wire.

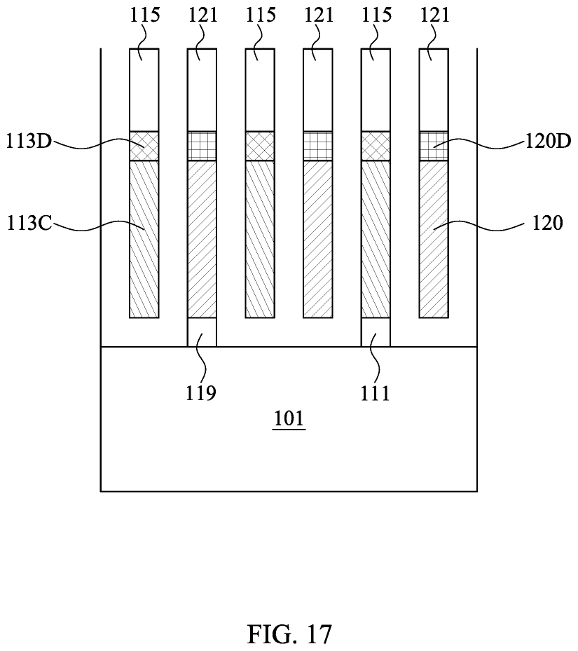

FIG. 17 is a cross-sectional view illustrating an intermediate stage of removing the spacer layer 105 in the formation of the semiconductor die structure 100, in accordance with some embodiments of the present disclosure. At the step S19 in the method 10 shown in FIG. 1, a plurality of suspended conductor blocks are formed over the substrate and connected to the first conductor block and the second conductor block. In some embodiments, the spacer layer 105 is removed to expose the substrate 101. In some embodiments, hydrofluoric (HF) cleanse may be ran to remove the spacer layer 105, while the first supporting backbone 111 and the second supporting backbone 119 are not etched. A first set of the conductor block 113C and the conductor block 120 (e.g., metal lines, wires) are disposed on the first supporting backbone 111 and the second supporting backbone 119, while a second set of the conductor block 113C and the conductor block 120 (e.g., metal lines, wires) are suspended above the substrate 101 between the first supporting backbone 111 and the second supporting backbone 119.

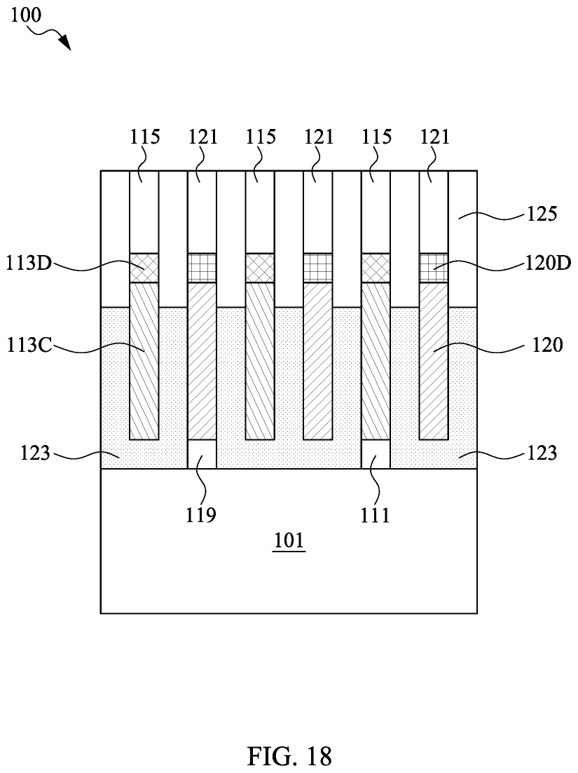

FIG. 18 is a cross-sectional view illustrating an intermediate stage of forming an energy removable layer 123 and a capping dielectric layer 125 in the formation of the semiconductor die structure 100, in accordance with some embodiments of the present disclosure. At the step S21 in the method 10 shown in FIG. 1, an energy removable layer and a capping dielectric layer are sequentially formed over the substrate. In some embodiments, the energy removable layer 123 and the capping dielectric layer 125 are sequentially formed over the substrate 101, in accordance with some embodiments.

In some embodiments, the material of the energy removable layer 123 includes a thermal decomposable material. In some other embodiments, the material of the energy removable layer 123 includes a photonic decomposable material, an e-beam decomposable material, or another applicable energy decomposable material. Specifically, in some embodiments, the material of the energy removable layer 123 includes a base material and a decomposable porogen material that is substantially removed once being exposed to an energy source (e.g., heat).

In some embodiments, the base material includes hydrogen silsesquioxane (HSQ), methylsilsesquioxane (MSQ), porous polyarylether (PAE), porous SiLK, or porous silicon oxide (SiO2), and the decomposable porogen material includes a porogen organic compound, which can provide porosity to the space originally occupied by the energy removable layer 123 in the subsequent processes.

In addition, the capping dielectric layer 125 is made of silicon oxide, silicon nitride, silicon oxynitride, or multilayers thereof. In some embodiments, the capping dielectric layer 125 is made of a low-k dielectric material. In addition, the energy removable layer 123 and the capping dielectric layer 125 may be formed by deposition processes. In some embodiments, the deposition processes include chemical vapor deposition (CVD), physical vapor deposition (PVD), atomic layer deposition (ALD), spin-coating, or another applicable process.

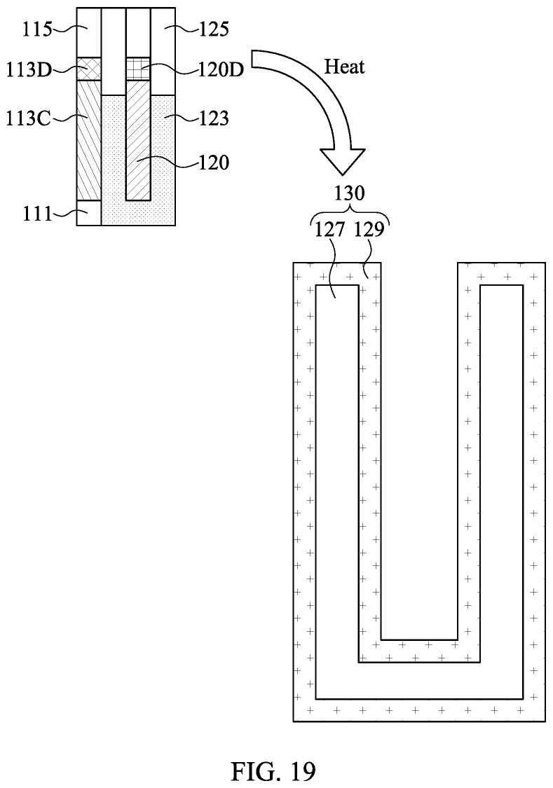

FIG. 19 is a cross-sectional view illustrating an intermediate stage of forming air gaps 127 and liner layers 129 in the formation of the semiconductor die structure 100, in accordance with some embodiments of the present disclosure. At the step S23 in the method 10 shown in FIG. 1, a heat treatment process is performed to transform the energy removable layer into air gaps enclosed by liner layers. In some embodiments, a heat treatment process is performed to transform the energy removable layer 123 into an air gap structure 130 including an air gap 127 and a liner layer 129 enclosing the air gap 127. In some embodiments, the heat treatment process is used to remove the decomposable porogen materials of the energy removable layer 123 to generate pores, and the base materials of the energy removable layer 123 is accumulated at the edges of the energy removable layer 123 to form the liner layers 129. The pores are filled by air after the decomposable porogen materials are removed, such that the air gaps 127 are obtained inside the remaining portions of the energy removable layer 123. In some embodiments, the air gaps 127 may be a vacuum (e.g., pump out the gas in the air gaps). In some embodiments, the air gaps 127 may include an inert gas (e.g., nitrogen, helium, argon, air, etc.).

In some other embodiments, the heat treatment process can be replaced by a light treatment process, an e-beam treatment process, a combination thereof, or another applicable energy treatment process. For example, an ultra-violet (UV) light or laser light may be used to remove the decomposable porogen materials of the energy removable layer 123, and the air gaps 127 is then obtained.

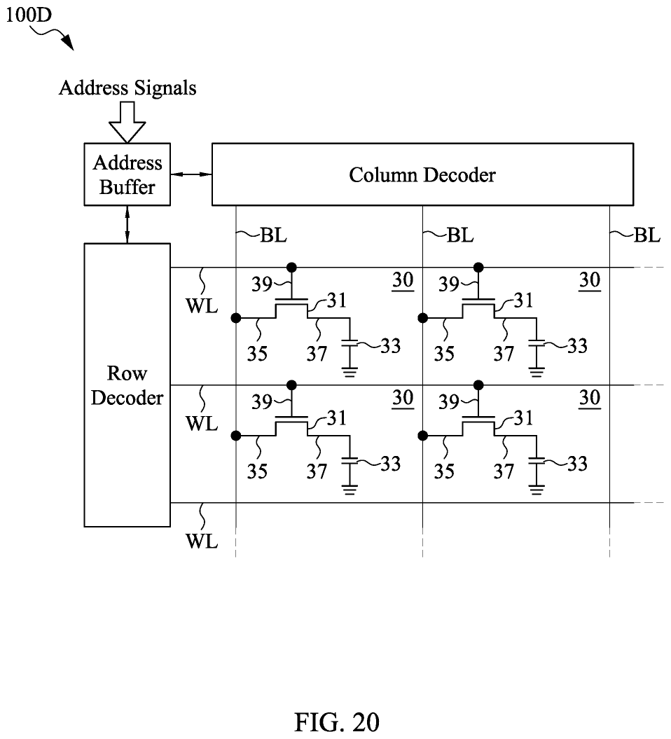

FIG. 20 is a schematic illustration of an exemplary integrated circuit, such as a memory device 1000, including an array of memory cells 30 in accordance with some embodiments. In some embodiments, the memory device 1000 includes a dynamic random access memory (DRAM) device. In some embodiments, the memory device 1000 includes a number of memory cells 30 arranged in a grid pattern and including a number of rows and columns. The number of memory cells 30 may vary depending on system requirements and fabrication technology.

In some embodiments, each of the memory cells 30 includes an access device and a storage device. The access device is configured to provide controlled access to the storage device. In particular, the access device is a field effect transistor (FET) 31 and the storage device is a capacitor 33, in accordance with some embodiments. In each of the memory cells 30, the FET 31 includes a drain 35, a source 37 and a gate 39. One terminal of the capacitor 33 is electrically connected to the source 37 of the FET 31, and the other terminal of the capacitor 33 may be electrically connected to the ground. In addition, in each of the memory cells 30, the gate 39 of the FET 31 is electrically connected to a word line WL, and the drain 35 of the FET 31 is electrically connected to a bit line BL.

The above description mentions the terminal of the FET 31 electrically connected to the capacitor 33 is the source 37, and the terminal of the FET 31 electrically connected to the bit line BL is the drain 35. However, during read and write operations, the terminal of the FET 31 electrically connected to the capacitor 33 may be the drain, and the terminal of the FET 31 electrically connected to the bit line BL may be the source. That is, either terminal of the FET 31 could be a source or a drain depending on the manner in which the FET 31 is being controlled by the voltages applied to the source, the drain and the gate.

By controlling the voltage at the gate 39 via the word line WL, a voltage potential may be created across the FET 30 such that the electrical charge can flow from the drain 35 to the capacitor 33. Therefore, the electrical charge stored in the capacitor 33 may be interpreted as a binary data value in the memory cell 30. For example, a positive charge above a threshold voltage stored in the capacitor 33 may be interpreted as binary “1.” If the charge in the capacitor 33 is below the threshold value, a binary value of “0” is said to be stored in the memory cell 30.

The bit lines BL are configured to read and write data to and from the memory cells 30. The word lines WL are configured to activate the field effect transistors (FET) 31 to access a particular row of the memory cells 30. Accordingly, the memory device 1000 also includes a periphery region which may include an address buffer, a row decoder and a column decoder. The row decoder and the column decoder selectively access the memory cells 30 in response to address signals that are provided to the address buffer during read, write and refresh operations. The address signals are typically provided by an external controller such as a microprocessor or another type of memory controller.

Referring back to FIG. 19, the air gaps 127 are formed in the cell region 300 (i.e., the pattern-dense region) of the semiconductor die structure 100, while no air gap is formed in the peripheral region 400 (i.e., the pattern-loose region) of the semiconductor die structure 100.

Embodiments of the semiconductor die structure 100 are provided in the disclosure. The semiconductor die structure 100 includes a plurality of air gaps 127, and the conductor block 113C and the conductor block 120 are separated from the each other by the air gaps 127. Therefore, the parasitic capacitance between the conductive contacts may be reduced. As a result, the overall device performance may be improved (i.e., the decreased power consumption and resistive-capacitive (RC) delay), and the yield rate of the semiconductor device may be increased.

The semiconductor die structure 100 described above is provided for illustrative purposes. However, the present disclosure is not limited thereto. In other embodiments, the conductor block 113 and the conductor block 120 of the semiconductor die structure 100 can be replaced by other structures.

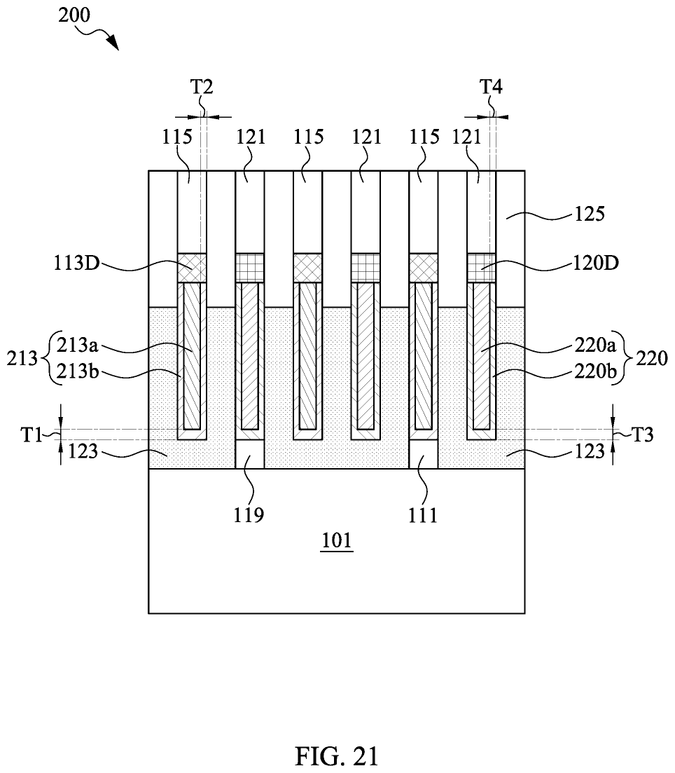

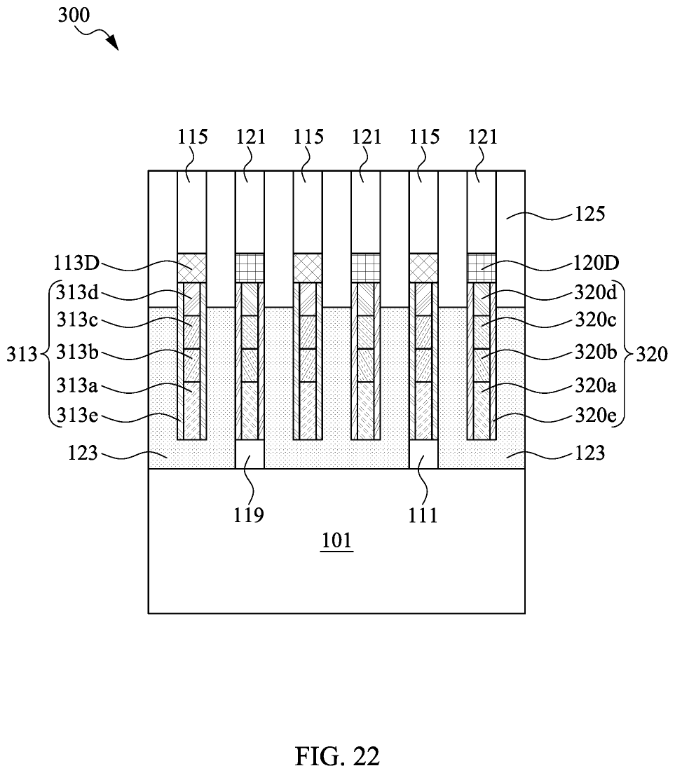

Reference is made to FIG. 21 and FIG. 22. FIG. 21 is a schematic diagram of a semiconductor die structure 200 according to other embodiments of the present disclosure. FIG. 22 is a schematic diagram of a semiconductor die structure 300 according to various embodiments of the present disclosure.

As illustrated in FIG. 21, the semiconductor die structure 200 is similar to the semiconductor die structure 100 and includes a substrate 101, a plurality of conductor blocks 213, a plurality of metal silicide layers 113D, a plurality of conductor blocks 220, a plurality of metal silicide layers 120D, a plurality of first hard masks 115, a plurality of second hard masks 121, a first supporting backbone 111, a second supporting backbone 119, an energy removable layer 123, and a capping dielectric layer 125.

In some embodiments, the substrate 101, the metal silicide layers 113D, the metal silicide layers 120D, the first hard masks 115, the second hard masks 121, the first supporting backbone 111, the second supporting backbone 119, the energy removable layer 123, and the capping dielectric layer 125 of the semiconductor die structure 200 are the same as those elements of the semiconductor die structure 100. Furthermore, the manufacturing processes for the above elements in the semiconductor die structure 200 are the same as those manufacturing processes for those elements in the semiconductor die structure 100. Hence, the details of these elements are not repeated herein.

As illustrated in FIG. 21, one of the conductor block 213 is disposed above the first supporting backbone 111, and one of the conductor block 220 is disposed above the second supporting backbone 119.

Each of the conductor blocks 213 is disposed in the energy removable layer 123 and protruding from the top surface of the energy removable layer 123. A top surface of each of the conductor blocks 213 is covered by the respective metal silicide layer 113D. Sidewalls of a top portion of each of the conductor blocks 213 is surrounded by the capping dielectric layer 125.

Each of the conductor blocks 213 includes a conductive layer 213a and a barrier layer 213b. The 231b has a U-shape and is in contact with the energy removable layer 123, the capping dielectric layer 125, and the respective metal silicide layer 113D. The conductive layer 213a is disposed in the U-shape barrier layer 213b. In some embodiments, the conductive layer 213a has a rectangular cross-sectional view.

The barrier layer 213b has a bottom portion and two side portions, and the bottom portion connects one of the side portions to another. In some embodiments, a thickness T1 of the bottom portion is greater than a thickness T2 of each of the side portions.

In some embodiments, the barrier layer 213b include titanium (Ti), titanium nitride (TiN), or a combination thereof, and the conductive layer 213a include tungsten (W).

Each of the conductor blocks 220 is disposed in the energy removable layer 123 and protruding from the top surface of the energy removable layer 123. A top surface of each of the conductor blocks 220 is covered by the respective metal silicide layers 120D. Sidewalls of a top portion of each of the conductor blocks 220 is surrounded by the capping dielectric layer 125.

Each of the conductor blocks 220 includes a conductive layer 220a and a barrier layer 220b. The barrier layer 220b has a U-shape and is in contact with the energy removable layer 123, the capping dielectric layer 125, and the respective metal silicide layer 120D. The conductive layer 220a is disposed in the U-shape barrier layer 220b. In some embodiments, the conductive layer 220a has a rectangular cross-sectional view.

The barrier layer 220b has a bottom portion and two side portions, and the bottom portion connects one of the side portions to another. In some embodiments, a thickness T3 of the bottom portion is greater than a thickness T4 of each of the side portions.

In some embodiments, the barrier layer 220b include titanium (Ti), titanium nitride (TiN), or a combination thereof, and the conductive layer 220a include tungsten (W).

In some embodiments, the conductor blocks 213 and the conductor blocks 220 are identical. In such embodiments, the thickness T1 is equal to the thickness T3, and the thickness T2 is equal to the thickness T4.

In some embodiments, the conductor block 213 and the conductor blocks 220 are void-free conductor blocks, namely, there is no air gap or vacuum void exists in the conductor block 213 and the conductor blocks 220.

For the formation of the conductor blocks 213, please refer to FIG. 5 to FIG. 7. In some embodiments, after the carbon hard mask 109 is removed, a barrier material is formed to fill the regions between the spacer 105 and to cover the top end of the spacer 105. The barrier material include Ti, TiN, or a combination thereof. It should be noted that the profile of the barrier material is the same as the conductor block 113 shown in FIG. 6. Next, a planarization process is performed to remove the barrier material above the spacer 105, and the spacer 105 is exposed. In some embodiments, the planarization process is a CMP process. The remaining barrier material after the planarization process has the profile the same as the conductor block 113A shown in FIG. 7.

Please refer to FIG. 8. A portion of the barrier material between the spacer 105 is removed by a recessing process such as an etching back process to form a plurality of barrier material embedded in the spacer layer 105. A top end of the barrier material after the recessing process is lower than that of the spacer layer 105.

Before the metal silicide layers 113D are formed, the barrier material is etched to form the barrier layer 213b. In some embodiments, a photolithography process is performed to the barrier material. The side portions of the barrier layer 213b is masked during the photolithography process, and other portion is not masked so as to be etched. After the barrier layer 213b is formed, the conductive layer 213a is formed in the barrier layer 213b. After the conductive layer 213a is formed, the conductor blocks 213 are formed.

In alternative embodiments, the barrier layer 213b is formed by other method. In such embodiments, the barrier material is not formed. Instead, the barrier layer 213b is formed by an anisotropic deposition process between the spacer 105 after the carbon hard mask 109 is removed. Because of the anisotropic deposition process, the thickness T1 of the bottom portion of the barrier 213b can be greater than the thickness T2 of the side portion of the barrier 213b.

For the formation of the conductor blocks 220, please refer to FIG. 14. In some embodiments, the carbon hard mask 117 is removed, a barrier material is formed to fill the regions between the spacer 105 and to cover the top end of the spacer 105. The barrier material include Ti, TiN, or a combination thereof. Next, a planarization process may be performed to remove the barrier material above the spacer 105, and the spacer 105 is exposed. In some embodiments, the planarization process is a CMP process. A portion of the barrier material between the spacer 105 is removed by a recessing process such as an etching back process to form a plurality of barrier material embedded in the spacer layer 105. A top end of the barrier material after the recessing process is lower than that of the spacer layer 105.

Before the metal silicide layers 120D are formed, the barrier material is etched to form the barrier layer 220b. In some embodiments, a photolithography process is performed to the barrier material. The side portions of the barrier layer 220b is masked during the photolithography process, and other portion is not masked so as to be etched. After the barrier layer 220b is formed, the conductive layer 220a is formed in the barrier layer 220b. After the conductive layer 220a is formed, the conductor blocks 220 are formed.

In alternative embodiments, the barrier layer 220b is formed by other method. In such embodiments, the barrier material is not formed. Instead, the barrier layer 220b is formed by an anisotropic deposition process between the spacer 105 after the carbon hard mask 117 is removed. Because of the anisotropic deposition process, thickness T3 of the bottom portion of the barrier 220b can be greater than the thickness T4 of the side portion of the barrier 220b.

The energy removable layer 123 of the semiconductor die structure 200 shown in FIG. 21 is then transformed to the air gaps 127 and the liner layers 129 as illustrated in FIG. 19. In some embodiments, a heat treatment process is performed to transform the energy removable layer 123 into an air gap structure 130 including an air gap 127 and a liner layer 129 enclosing the air gap 127. In some embodiments, the heat treatment process is used to remove the decomposable porogen materials of the energy removable layer 123 to generate pores, and the base materials of the energy removable layer 123 is accumulated at the edges of the energy removable layer 123 to form the liner layers 129. The pores are filled by air after the decomposable porogen materials are removed, such that the air gaps 127 are obtained inside the remaining portions of the energy removable layer 123. In some embodiments, the air gaps 127 may be a vacuum (e.g., pump out the gas in the air gaps). In some embodiments, the air gaps 127 may include an inert gas (e.g., nitrogen, helium, argon, air, etc.)

In some other embodiments, the heat treatment process can be replaced by a light treatment process, an e-beam treatment process, a combination thereof, or another applicable energy treatment process. For example, an ultra-violet light or laser light may be used to remove the decomposable porogen materials of the energy removable layer 123, and the air gaps 127 is then obtained.

In some embodiments, the semiconductor die structure 200 is part of DRAM such as the memory device 1000 shown in FIG. 20.

Reference is made to FIG. 22. The semiconductor die structure 300 is similar to the semiconductor die structure 100 and includes a substrate 101, a plurality of conductor blocks 313, a plurality of metal silicide layers 113D, a plurality of conductor blocks 320, a plurality of metal silicide layers 120D, a plurality of first hard masks 115, a plurality of second hard masks 121, a first supporting backbone 111, a second supporting backbone 119, an energy removable layer 123, and a capping dielectric layer 125.

In some embodiments, the substrate 101, the metal silicide layers 113D, the metal silicide layers 120D, the first hard masks 115, the second hard masks 121, the first supporting backbone 111, the second supporting backbone 119, the energy removable layer 123, and the capping dielectric layer 125 of the semiconductor die structure 300 are the same as those elements of the semiconductor die structure 100. Furthermore, the manufacturing processes for the above elements in the semiconductor die structure 300 are the same as those manufacturing processes for those elements in the semiconductor die structure 100. Hence, the details of these elements are not repeated herein.

As illustrated in FIG. 22, one of the conductor block 313 is disposed above the first supporting backbone 111, and one of the conductor block 320 is disposed above the second supporting backbone 119.

Each of the conductor blocks 313 is disposed in the energy removable layer 123 and protruding from the top surface of the energy removable layer 123. A top surface of each of the conductor blocks 313 is covered by the respective metal silicide layers 113D. Sidewalls of a top portion of each of the conductor blocks 313 is surrounded by the capping dielectric layer 125.

Each of the conductor blocks 313 includes a first contact 313a, a second contact 313b, a third contact 313c, a fourth contact 313d, and two spacers 313e. The first contact 313a, the second contact 313b, the third contact 313c, and the fourth contact 313d are sequentially stacked, and are sandwiched by the spacers 313e. The first contact 313a, the second contact 313b, the third contact 313c, and the fourth contact 313d have the substantially same width, therefore, each of the spacers 313e has a straight side surface in contact with the first contact 313a, the second contact 313b, the third contact 313c, and the fourth contact 313d.

One of the conductor blocks 313 is disposed above and in contact with the first supporting backbone 111. The first contacts 313a of the rest of the conductor blocks 313 are in contact with the energy removable layer 123.

In FIG. 22, a top surface of the third contact 313c is lower than the top end of the energy removable layer 123. In other words, a bottom surface of the fourth contact 331d is lower than the energy removable layer 123.

In some embodiments, the first contact 313a is formed of a conductive material such as doped polysilicon, metal, metal nitride, or metal silicide. In some embodiments, the second contact 313b is formed of doped polysilicon. In some embodiments, the third contact 313c is formed of conductive material such as tungsten, aluminum, copper, nickel, or cobalt. In some embodiments, the fourth contact 313d is formed of conductive material such as tungsten, aluminum, copper, nickel, or cobalt. In some embodiments, the third contact 313c and the fourth contact 313d may be formed by the same material. In some embodiments, the spacers 313e are formed of silicon oxide, silicon nitride, silicon oxynitride, or silicon nitride oxide.

Each of the conductor blocks 320 is disposed in the energy removable layer 123 and protruding from the top surface of the energy removable layer 123. A top surface of each of the conductor blocks 320 is covered by the respective metal silicide layer 120D. Sidewalls of a top portion of each of the conductor blocks 320 is surrounded by the capping dielectric layer 125.

Each of the conductor blocks 320 includes a first contact 320a, a second contact 320b, a third contact 320c, a fourth contact 320d, and two spacers 320e. The first contact 320a, the second contact 320b, the third contact 320c, and the fourth contact 320d are sequentially stacked, and are sandwiched by the spacers 320e. The first contact 320a, the second contact 320b, the third contact 320c, and the fourth contact 320d have the substantially same width, therefore, each of the spacers 320e has a straight side surface in contact with the first contact 320a, the second contact 320b, the third contact 320c, and the fourth contact 320d.

One of the conductor blocks 320 is disposed above and in contact with the second supporting backbone 119. The first contacts 320a of the rest of the conductor blocks 320 are in contact with the energy removable layer 123.

In FIG. 22, a top surface of the third contact 320c is lower than the top end of the energy removable layer 123. In other words, a bottom surface of the fourth contact 320d is lower than the energy removable layer 123.

In some embodiments, the first contact 320a is formed of a conductive material such as doped polysilicon, metal, metal nitride, or metal silicide. In some embodiments, the second contact 320b is formed of doped polysilicon. In some embodiments, the third contact 320c is formed of conductive material such as tungsten, aluminum, copper, nickel, or cobalt. In some embodiments, the fourth contact 320d is formed of conductive material such as tungsten, aluminum, copper, nickel, or cobalt. In some embodiments, the third contact 320c and the fourth contact 320d may be formed by the same material. In some embodiments, the spacers 320e are formed of silicon oxide, silicon nitride, silicon oxynitride, or silicon nitride oxide.

In some embodiments, the conductor blocks 313 and the conductor blocks 320 are identical.

For the formation of the conductor blocks 313, please refer to FIG. 5. In some embodiments, after the carbon hard mask 109 is removed, the first contact 313a is deposited into the regions between the spacer 105. Next, the second contact 313b is deposited over the first contact 313a, the third contact 313c is deposited over the second contact 313b, and the fourth contact 313d is disposed over the third contact 313c. It should be noted that the materials of the first contact 313a, the second contact 313b, the third contact 313c, and the fourth contact 313d may deposited on the top surface of the spacer 105, and those materials are removed after the fourth contact 313d is formed by a planarization process, such as a CMP process.

After the fourth contact 313d is formed, an etch process is performed to remove the side portions of the contacts 313a-313d, in which the side portions are in contact with the spacer 105. The side portions are masked during the etching process. A photolithography process may be used to mask the side portions.

The spacer 313e are formed into the region originally occupied by the side portions of the contacts 313a-313d, and the conductor blocks 313 are formed.

For the formation of the conductor blocks 320, please refer to FIG. 14. In some embodiments, after the carbon hard mask 117 is removed, the first contact 320a is deposited into the regions between the spacer 105. Next, the second contact 320b is deposited over the first contact 320a, the third contact 320c is deposited over the second contact 320b, and the fourth contact 320d is disposed over the third contact 320c. It should be noted that the materials of the first contact 313a, the second contact 313b, the third contact 313c, and the fourth contact 313d may deposited on the top surface of the spacer 105, and those materials are removed after the fourth contact 313d is formed by a planarization process, such as a CMP process.

After the fourth contact 320d is formed, an etch process is performed to remove the side portions of the contacts 320a-320d, in which the side portions are in contact with the spacer 105. The side portions are masked during the etching process. A photolithography process may be used to mask the side portions.

The spacer 320e are formed into the region originally occupied by the side portions of the contacts 320a-320d, and the conductor blocks 320 are formed.

The energy removable layer 123 of the semiconductor die structure 300 shown in FIG. 22 is then transferred to the air gaps 127 and the liner layers 129 as illustrated in FIG. 19. In some embodiments, a heat treatment process is performed to transform the energy removable layer 123 into an air gap structure 130 including an air gap 127 and a liner layer 129 enclosing the air gap 127. In some embodiments, the heat treatment process is used to remove the decomposable porogen materials of the energy removable layer 123 to generate pores, and the base materials of the energy removable layer 123 is accumulated at the edges of the energy removable layer 123 to form the liner layers 129. The pores are filled by air after the decomposable porogen materials are removed, such that the air gaps 127 are obtained inside the remaining portions of the energy removable layer 123. In some embodiments, the air gaps 127 may be a vacuum (e.g., pump out the gas in the air gaps). In some embodiments, the air gaps 127 may include an inert gas (e.g., nitrogen, helium, argon, air, etc.)

In some other embodiments, the heat treatment process can be replaced by a light treatment process, an e-beam treatment process, a combination thereof, or another applicable energy treatment process. For example, an ultra-violet light or laser light may be used to remove the decomposable porogen materials of the energy removable layer 123, and the air gaps 127 is then obtained.

In some embodiments, the semiconductor die structure 300 is part of DRAM such as the memory device 1000 shown in FIG. 20.

One aspect of the present disclosure provides a semiconductor die structure including a substrate, a first supporting backbone, a first conductor block, and an air gap structure. The first supporting backbone is disposed on the substrate. The first conductor block is disposed on the first supporting backbone, and includes a first barrier layer and a first conductive layer disposed in the first barrier layer. The air gap structure is disposed on the substrate and in contact with the first supporting backbone and the first conductor block.

Another aspect of the present disclosure provides a semiconductor die structure including a substrate, a first supporting backbone, a second supporting backbone, a first conductor block, a second conductor block, and third conductor blocks. The first supporting backbone and the second supporting backbone are disposed on the substrate. The first conductor block is disposed on the first supporting backbone, and the second conductor block is disposed on the second supporting backbone. The third conductor blocks are disposed between the first conductor block and the second conductor block. The third conductor blocks are suspended on the substrate.

Yet another aspect of the present disclosure provides a method for preparing a semiconductor die structure, including: forming a first supporting backbone on the substrate; forming a first conductor block on the first supporting backbone; after forming the first conductor block, forming a second supporting backbone on the substrate; forming a second conductor block on the second supporting backbone; forming third conductor blocks suspended above the substrate; sequentially forming an energy removable layer and a capping dielectric layer over the substrate, wherein the first conductor block, the second conductor block and the third conductor blocks are spaced apart to each other by the energy removable layer; and performing a heat treatment process to transform the energy removable layer into an air gap structure including an air gap and a liner layer enclosing the air gap.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor die structure, comprising:
a substrate;
a first supporting backbone disposed on the substrate;
a second supporting backbone disposed on the substrate;
a first conductor block disposed on the first supporting backbone;
a second conductor block disposed on the second supporting backbone; and
a plurality of third conductor blocks disposed between the first conductor block and the second conductor block, wherein the plurality of third conductor blocks are suspended on the substrate.

2. The semiconductor die structure of claim 1, further comprising:
an air gap structure disposed on the substrate and between the first conductor block and the second conductor block,
wherein the plurality of the third conductor blocks are suspended over the air gap structure.

3. The semiconductor die structure of claim 2, wherein the air gap structure comprises:
an air gap; and
a liner layer enclosing the air gap.

4. The semiconductor die structure of claim 2, wherein the first conductor block comprises:
a first contact;
a second contact, disposed over the first contact;
a third contact, disposed over the second contact;
a fourth contact, disposed over the third contact; and
a plurality of spacers, wherein the first contact, the second contact, the third contact, and the fourth contact are sandwiched by the plurality of spacers.

5. The semiconductor die structure of claim 4, wherein the first contact and the plurality of spacers are in contact with the first supporting backbone.

6. The semiconductor die structure of claim 4, further comprising:
a first metal silicide, disposed over the first conductor block, wherein the first metal silicide is in contact with the fourth contact and the plurality of spacers; and
a first hard mask, disposed over the first metal silicide.

7. The semiconductor die structure of claim 6, further comprising:
a capping dielectric layer, disposed over the first hard mask, wherein the capping dielectric layer is in contact with the first hard mask, the first metal silicide, the plurality of spacers, and the air gap structure.

8. The semiconductor die structure of claim 4, wherein
the first contact comprises doped polysilicon, metal, metal nitride, or metal silicide,
the second contact comprises doped polysilicon,
the third contact comprises tungsten, aluminum, copper, nickel, or cobalt, and
the fourth contact comprises tungsten, aluminum, copper, nickel, or cobalt.

9. The semiconductor die structure of claim 4, wherein the plurality of spacers comprises silicon oxide, silicon nitride, silicon oxynitride, or silicon nitride oxide.

10. The semiconductor die structure of claim 4 wherein a top surface of the third contact is lower than a top surface of the air gap structure.

11. The semiconductor die structure of claim 10, wherein the first conductor block, the second conductor block, and the plurality of third conductor blocks are spaced apart from each other by the air gap structure.

12. A method for preparing a semiconductor die structure, comprising:
forming a first supporting backbone on a substrate;
forming a first conductor block on the first supporting backbone;
after forming the first conductor block, forming a second supporting backbone on the substrate;
forming a second conductor block on the second supporting backbone;
forming a plurality of third conductor blocks suspended above the substrate;
sequentially forming an energy removable layer and a capping dielectric layer over the substrate, wherein the first conductor block, the second conductor block and the plurality of third conductor blocks are spaced apart to each other by the energy removable layer; and
performing a heat treatment process to transform the energy removable layer into an air gap structure comprising an air gap and a liner layer enclosing the air gap.

13. The method of claim 12, wherein forming the first conductor block comprises:
performing an anisotropic deposition to form a barrier layer of the first conductor block, wherein the barrier layer has a U-shape; and
forming a conductive layer in the barrier layer.

14. The method of claim 13, wherein the barrier layer comprises a bottom portion and two side portions, wherein the bottom portion connects one of the two side portions to another one of the two side portions.

15. The method of claim 14, wherein a first thickness of the bottom portion is greater than a second thickness of the side portions.

16. The method of claim 12, wherein forming the first conductor block comprises:
sequentially forming a first contact, a second contact, a third contact, and a fourth contact;
removing side portions of the first contact, the second contact, the third contact, and the fourth contact; and
forming a plurality of spacers in regions originally occupied by the side portions.

17. The method of claim 16, wherein the plurality of spacers and the first contact are in contact with the first supporting backbone.

18. The method of claim 16, wherein a top surface of the third contact is lower a top surface of the air gap structure.
